(19) United States
(12) Patent Application Publication
(10) Pub. No.: US 2024/0162235 A1
(43) Pub. Date: May 16, 2024

(54) DISPLAY DEVICE AND MANUFACTURING METHOD THEREOF

(71) Applicant: Samsung Display Co., LTD., Yongin-si, Gyeonggi-do (KR)

(72) Inventors: Yeoung Keol WOO, Yongin-si (KR); Sang Wook LEE, Yongin-si (KR); Yeon Hong KIM, Yongin-si (KR); Yung Bin CHUNG, Yongin-si (KR)

(21) Appl. No.: 18/509,934

(22) Filed: Nov. 15, 2023

(30) Foreign Application Priority Data
Nov. 16, 2022 (KR) 10-2022-0153660

(51) Int. Cl. H01L 27/12; H01L 25/075; H01L 25/16

(52) U.S. Cl. CPC H01L 27/1225; H01L 25/0753; H01L 25/167; H01L 27/127

(57) ABSTRACT

A display device includes: a substrate; a first semiconductor layer and a dummy semiconductor layer on the same layer on a surface of the substrate and comprising the same material as each other; a second semiconductor layer overlapping the dummy semiconductor layer in a direction perpendicular to the surface of the substrate, the first semiconductor layer and the second semiconductor layer comprising different materials from each other; a first transistor comprising the first semiconductor layer, a first source electrode, and a first drain electrode, the first source electrode and the first drain electrode being connected to the first semiconductor layer; a second transistor comprising the second semiconductor layer, a second source electrode, and a second drain electrode, the second source electrode and the second drain electrode being connected to the second semiconductor layer; and a light- emitting element connected to the first transistor.

### CROSS-REFERENCE TO RELATED APPLICATION

This application claims priority to and the benefit of Korean Patent Application No. 10-2022-0153660, filed in the Korean Intellectual Property Office on Nov. 16, 2022, the entire content of which is incorporated herein by reference.

### BACKGROUND

### 1. Field

Aspects of embodiments of the present disclosure relate to a display device and a manufacturing method thereof.

### 2. Description of the Related Art

From among the types of display devices, a flat panel display device is in the spotlight because it can be lighter and thinner than other types of display devices.

From among the types of flat panel displays, a light emitting display device is a self-luminous display device that displays images by using a light emitting diode (LED) that emits light and, as such, does not require a separate light source. In addition, light emitting display devices are attracting attention as a next generation display device because they have relatively low power consumption, high luminance, and high reaction speed (e.g., high response time).

The aforementioned light emitting display device includes a light emitting diode (LED) and a plurality of pixels, each including a plurality of transistors and at least one capacitor for driving the light emitting diode (LED).

An oxide semiconductor may be used as a semiconductor layer of the transistor. However, oxygen defects exist inside the oxide semiconductor, and these oxygen defects act as carriers and may cause the semiconductor layer to operate more akin to a conductor rather than a semiconductor.

The above information disclosed in this Background section is for enhancement of understanding of the background of the present disclosure, and therefore, it may contain information that does not form the prior art that is already known to a person of ordinary skill in the art.

### SUMMARY

Embodiments of the present disclosure provide a display device with improved element characteristics of the oxide semiconductor and a manufacturing method thereof.

A display device, according to an embodiment of the present disclosure, includes: a substrate; a first semiconductor layer and a dummy semiconductor layer on the same layer on a surface of the substrate and comprising the same material as each other; a second semiconductor layer overlapping the dummy semiconductor layer in a direction perpendicular to the surface of the substrate, the first semiconductor layer and the second semiconductor layer comprising different materials from each other; a first transistor comprising the first semiconductor layer, a first source electrode, and a first drain electrode, the first source electrode and the first drain electrode being connected to the first semiconductor layer; a second transistor comprising the second semiconductor layer, a second source electrode, and a second drain electrode, the second source electrode and the second drain electrode being connected to the second semiconductor layer; and a light-emitting element connected to the first transistor.

The first semiconductor layer and the dummy semiconductor layer may include IGZO (indium gallium zinc oxide).

The display device of claim 2, wherein the second semiconductor layer may include indium tin gallium zinc oxide (ITGZO).

The display device may further include a first gate insulating layer between the dummy semiconductor layer and the second semiconductor layer, and the dummy semiconductor layer, the first gate insulating layer, and the second semiconductor layer may have the same planar shape.

The display device may further include a second gate insulating layer and a second gate electrode on the second semiconductor layer, and the second gate insulating layer and the second gate electrode may have the same planar shape.

A thickness of a portion of the second semiconductor layer overlapping the second gate insulating layer may be thicker than a thickness of a portion of the second semiconductor layer that does not overlap the second gate insulating layer.

The display device may further include a first gate insulating layer, a second gate insulating layer, and a first gate electrode on the first semiconductor layer, and the first gate insulating layer, the second gate insulating layer, and the first gate electrode may have the same planar shape.

A portion of the first semiconductor layer overlapping the first gate insulating layer may be thicker than a portion of the first semiconductor layer that does not overlap the first gate insulating layer.

A thickness of the dummy semiconductor layer and a thickness of the portion of the first semiconductor layer overlapping the first gate insulating layer may be the same.

The display device may further include a light blocking layer between the substrate and the first semiconductor layer, and the first source electrode may directly contact the light blocking layer.

The first source electrode, the first drain electrode, the second source electrode, and the second drain electrode may be on the same layer.

A manufacturing method of a display device, according to an embodiment of the present disclosure, includes: forming a first semiconductor material on a substrate; forming a first gate insulating layer on the first semiconductor material; forming a second semiconductor material on the first gate insulating layer, the second semiconductor material including at least the same material as the first semiconductor material; patterning the second semiconductor material to form a second semiconductor layer; and etching the first semiconductor material to form a dummy semiconductor layer overlapping the second semiconductor layer and a first semiconductor layer that does not overlap the second semiconductor layer.

The first semiconductor material may be indium gallium zinc oxide (IGZO).

The second semiconductor material may be indium tin gallium zinc oxide (ITGZO).

The manufacturing method may further include: forming a second gate insulating layer on the second semiconductor material; and forming a gate conductive layer on the second gate insulating layer.

The manufacturing method may further include etching the gate conductive layer, the second gate insulating layer, and the first gate insulating layer.

The gate conductive layer, the second gate insulating layer, and the first gate insulating layer may be etched by using a halftone mask.

After the etching of the gate conductive layer, the second gate insulating layer, and the first gate insulating layer, a portion of the second semiconductor layer may not overlap the second gate insulating layer.

A portion of the second semiconductor layer overlapping the second gate insulating layer may be thicker than the portion of the second semiconductor layer that does not overlap the second gate insulating layer.

After the etching of the gate conductive layer, the second gate insulating layer, and the first gate insulating layer, a portion of the first semiconductor layer may not overlap the first gate insulating layer.

According to embodiments, a display device exhibiting improved characteristics of the oxide semiconductor element and a manufacturing method thereof are provided.

### BRIEF DESCRIPTION OF THE DRAWINGS

FIG. 1 is a cross-sectional view of a display device according to an embodiment.

FIG. 2 to FIG. 8 show steps of a manufacturing process of a display device according to an embodiment.

### DETAILED DESCRIPTION

The present disclosure will be described more fully hereinafter with reference to the accompanying drawings, in which embodiments of the present disclosure are shown. As those skilled In the art would realize, the described embodiments may be modified in various different ways, all without departing from the spirit or scope of the present disclosure.

To more clearly and concisely describe the aspects and features of the present disclosure, parts of the embodiments that are not necessary to understand the present disclosure may be omitted or may not be described.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Further, in the specification, the phrase “on a plane” means when an object portion is viewed from above, and the phrase “on a cross-section” means when a cross-section taken by vertically cutting an object portion is viewed from the side.

Hereinafter, a display device and a manufacturing method thereof according to embodiments of the present disclosure will be described, in detail, with reference to accompanying drawings.

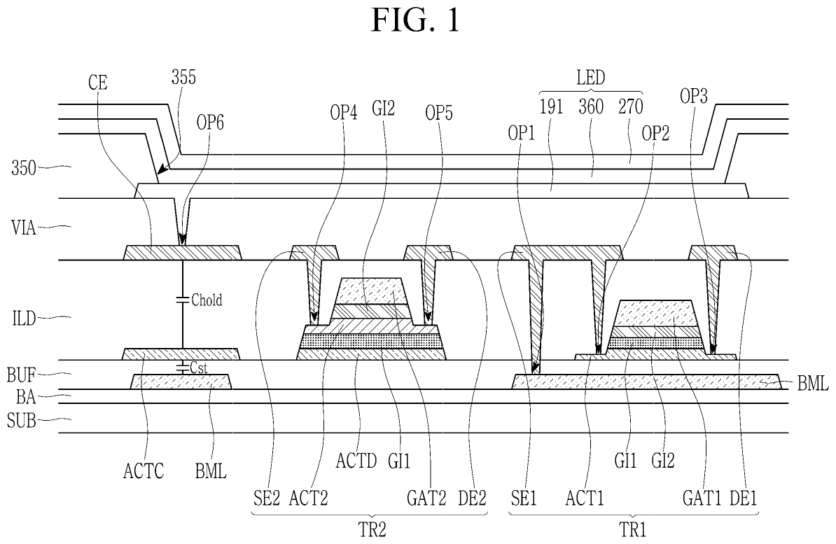

FIG. 1 is a cross-sectional view of a display device according to an embodiment. FIG. 1 is a schematically illustration for ease of description and understanding, and accordingly, the present disclosure is not limited thereto.

Referring to FIG. 1, a display device, according to the illustrated embodiment, includes a driving transistor TR1 and a switching transistor TR2. In this embodiment, a first semiconductor layer ACT1 of the driving transistor TR1 and a second semiconductor layer ACT2 of the switching transistor TR2 include different materials from each other, and a dummy semiconductor layer ACTD made of the same material as the first semiconductor layer ACT1 of the driving transistor TR1 may be positioned under the second semiconductor layer ACT2 of the switching transistor TR2. Through this structure, a negative shift of the switching transistor TR2 may be prevented, the reliability of the transistor may secured, and a driving range in a low gray range may be improved. In addition, the process of manufacturing the display device may be simplified by reducing the number of masks used in the process.

Hereinafter, the layered structure of the display device according to an embodiment will be described, in detail, with reference to FIG. 1.

Referring to FIG. 1, a substrate SUB is positioned (or provided). The substrate SUB may include at least one from among polystyrene, polyvinyl alcohol, poly(methyl methacrylate), polyethersulfone, polyacrylate, polyetherimide, polyethylene naphthalate, polyethylene terephthalate, polyphenylene sulfide, polyarylate, polyimide, polycarbonate, cellulose triacetate, and cellulose acetate propionate. The substrate SUB may be a rigid substrate or a flexible substrate configured to be bent, folded, rolled, etc. The substrate SUB may be a single layer or may have a multi-layer structure. The substrate SUB may have a structure in which at least one base layer and at least one inorganic layer including a sequentially stacked polymer resin are alternately stacked.

A barrier layer BA may be positioned on the substrate SUB. The barrier layer BA may include a silicon oxide (SiOₓ), a silicon nitride (SiNₓ), or a silicon oxynitride (SiOₓN_{y}), and amorphous silicon (Si). The barrier layer BA may have a multi-layer structure, but in some embodiments, the barrier layer BA may be omitted.

A light blocking layer BML may be positioned on the barrier layer BA. The light blocking layer BML may include aluminum (Al), silver (Ag), magnesium (Mg), gold (Au), nickel (Ni), chromium (Cr), calcium (Ca), molybdenum (Mo), titanium (Ti), tungsten (W), copper (Cu), and/or a metal oxide and may be a single layer or may have a multi-layer structure including the same.

A buffer layer BUF may be positioned on the light blocking layer BML. The buffer layer BUF may include one or more of a silicon oxide (SiOₓ), a silicon nitride (SiNₓ), or a silicon oxynitride (SiOₓN_{y}), and amorphous silicon (Si).

The buffer layer BUF may have a first opening OP1 overlapping the light blocking layer BML. The first source electrode SE1 may be connected to the light blocking layer BML via the first opening OP1.

A first semiconductor layer ACT1 may be positioned on the buffer layer BUF. A dummy semiconductor layer ACTD and a capacitor semiconductor layer ACTC including the same material as the first semiconductor layer ACT1 may be positioned on the same layer as the first semiconductor layer ACT1 (e.g., the first semiconductor layer ACT1, the dummy semiconductor layer ACTD, and the capacitor semiconductor layer ACTC may be formed concurrently). The first semiconductor layer ACT1 may be part of a driving transistor TR1. The dummy semiconductor layer ACTD may be positioned to overlap the switching transistor TR2. Although described in more detail below, the dummy semiconductor layer ACTD may prevent a negative shift of the switching transistor and may prevent Vth from being shortened by removing an oxygen vacancy from the second semiconductor layer ACT2 of the switching transistor TR2. The capacitor semiconductor layer ACTC may constitute a storage capacitor Cst with the overlapping light blocking layer BML. In some embodiments, the capacitor semiconductor layer ACTC may be omitted.

The first semiconductor layer ACT1, the dummy semiconductor layer ACTD, and the capacitor semiconductor layer ACTC may include IGZO. The driving transistor TR1 may include indium gallium zinc oxide (IGZO), which is an oxide semiconductor suitable for high VDS and VGS, as a semiconductor layer. In such an embodiment, the low gray expression of the driving transistor TR1 may be improved and the driving transistor TR1 may have a relatively high driving range. However, because IGZO has relatively low mobility and limited D/S reduction, the semiconductor layer of the driving transistor TR1 may include IGZO and the semiconductor layer of other transistors may include a material other than IGZO.

Next, a first gate insulating layer GI1 may be positioned on the first semiconductor layer ACT1 and the dummy semiconductor layer ACTD. The first gate insulating layer GI1 may include a silicon oxide (SiOₓ), a silicon nitride (SiNₓ), or a silicon oxynitride (SiOₓN_{y}), and may be a single layer or may have a multi-layer structure including the same.

The first gate insulating layer GI1 may be positioned to overlap the entire (e.g., to entirely overlap or cover an upper surface of the) dummy semiconductor layer ACTD. The first gate insulating layer GI1 is positioned to overlap a portion of the first semiconductor layer ACT1, and another region (e.g., a peripheral region) of the first semiconductor layer ACT1 may not be overlapped by (e.g., may not be covered by or may be exposed by) the first gate insulating layer GI1. The partial region of the first semiconductor layer ACT1 that is not overlapped by the first gate insulating layer GI1 may contact the source electrode SEI and the drain electrode DE1. In FIG. 1, the portion of the first semiconductor layer ACT1 that is not overlapped by the first gate insulating layer GI1 may be thinner than the portion of the first semiconductor layer ACT1 that is overlapped by the first gate insulating layer GI1. Such a structure may be formed by using a halftone mask in the manufacturing process. The detailed manufacturing method will be described later.

Next, a second semiconductor layer ACT2 may be positioned on the first gate insulating layer GI1 (e.g., on the first gate insulating layer GL1 of the switching transistors TR2). The second semiconductor layer ACT2 may be part of the switching transistor TR2. The second semiconductor layer ACT2 may include indium tin gallium zinc oxide (ITGZO). ITGZO has relatively high mobility and is desirable for switching transistor. However, because ITGZO has a lot of oxygen vacancies (Vo), a Vth short may occur. This problem may be mitigated through oxygen diffusion from the first gate insulating layer GI1 and the second gate insulating layer GI2, but oxygen diffusion from the first gate insulating layer GI1 and the second gate insulating layer GI2 by itself may not fully eliminate Vo (the oxygen vacancies) in ITGZO. In addition, because hydrogen diffused from first gate insulating layer GI1 and the second gate insulating layer GI2 may act as a carrier, oxygen diffusion from the first gate insulating layer GI1 and the second gate insulating layer GI2 is limited because the material of the first gate insulating layer GI1 and the second gate insulating layer GI2 should be a low hydrogen material.

However, according to embodiments of the present disclosure, the dummy semiconductor layer ACTD including the same material as the first semiconductor layer ACT1 may be positioned under the second semiconductor layer ACT2. Because the IGZO in the dummy semiconductor layer ACTD supplies oxygen to the ITGZO in the second semiconductor layer ACT2, the oxygen vacancy (Vo) in ITGZO may be substantially or entirely removed. Therefore, the negative shift and the Vth short of the second transistor TR2 may be prevented.

Next, a second gate insulating layer GI2 may be positioned on the second semiconductor layer ACT2. The second gate insulating layer GI2 may include a silicon oxide (SiOₓ), a silicon nitride (SiNₓ), or a silicon oxynitride (SiOₓN_{y}) and may be a single layer or may have a multi-layer structure including the same. In the region of the driving transistor TR1, the second gate insulating layer GI2 may be positioned on the first gate insulating layer GI1 and may have the same planar shape as the first gate insulating layer GI1. In the region of the switching transistor TR2, the second gate insulating layer GI2 is positioned to overlap a portion of the second semiconductor layer ACT2, and another portion of the second semiconductor layer ACT2 may not be overlapped by the second gate insulating layer GI2. The partial region of the second semiconductor layer ACT2 that is not overlapped by the second gate insulating layer GI2 contacts the source electrode SE2 and the drain electrode DE2. In FIG. 1, the partial region of the second semiconductor layer ACT2 that is not overlapped by the second gate insulating layer GI2 may be thinner than the region of the second semiconductor layer ACT2 that is overlapped by the second gate insulating layer GI2. This structure may be formed by using a halftone mask in the manufacturing process. The detailed manufacturing method will be described later.

Next, the gate electrode GAT may be positioned on the second gate insulating layer GI2. The gate electrode GAT may include a first gate electrode GAT1 of the driving transistor TR1 and a second gate electrode GAT2 of the switching transistor TR2. The gate electrode GAT may include molybdenum (Mo), aluminum (Al), copper (Cu), titanium (Ti), and a metal oxide and may be a single layer or may have a multi-layer structure including the same. The planar shape of the first gate electrode GAT1 of the driving transistor TR1 may be the same as that of the first gate insulating layer GI1 and the second gate insulating layer GI2. The planar shape of the second gate electrode GAT2 of the switching transistor TR2 may be the same as that of the second gate insulating layer GI2.

An interlayer insulating layer ILD may be positioned on the gate electrode GAT. The interlayer insulating layer ILD may include a silicon oxide (SiOₓ), a silicon nitride (SiNₓ), or a silicon oxynitride (SiOₓN_{y}) and may be a single layer or may have a multi-layer structure including the same. When the interlayer insulating layer ILD has a multi-layer structure including a silicon nitride and a silicon oxide, the layer including the silicon nitride may be positioned closer to the substrate SUB than the layer including the silicon oxide is.

The Interlayer Insulating layer ILD may have a first opening OP1 overlapping (e.g., open to) the light blocking layer BML, a second opening OP2 and a third opening OP3 overlapping the first semiconductor layer ACT1, and a fourth opening OP4 and a fifth opening OP5 overlapping the second semiconductor layer ACT2.

A data conductive layer DAT is positioned on the interlayer insulating layer ILD. The data conductive layer DAT may include aluminum (Al), silver (Ag), magnesium (Mg), gold (Au), nickel (Ni), chromium (Cr), calcium (Ca), molybdenum (Mo), titanium (Ti), tungsten (W), and/or copper (Cu), and a metal oxide thereof and may be a single layer or may have a multi-layer structure including the same. The data conductive layer DAT may include a first source electrode SE1, a first drain electrode DE1, a second source electrode SE2, a second drain electrode DE2, and a storage electrode CE.

The first source electrode SE1 may be in contact with the light blocking layer BML in (e.g., via) the first opening OP1 and the first semiconductor layer ACT1 in the second opening OP2. The first drain electrode DE1 may contact the first semiconductor layer ACT1 in the third opening OP3.

The second source electrode SE2 may contact the second semiconductor layer ACT2 in the fourth opening OP4. The second drain electrode DE2 may contact the second semiconductor layer ACT2 in the fifth opening OP5.

The first semiconductor layer ACT1, the first gate electrode GAT1, the first source electrode SE1, and first drain electrode DE1 may constitute the driving transistor TR1. The second semiconductor layer ACT2, the second gate electrode GAT2, the second source electrode SE2, and the second drain electrode DE2 may constitute the switching transistor TR2.

The storage electrode CE may constitute a hold capacitor Chold along with the capacitor semiconductor layer ACTC.

An insulating layer VIA may be positioned on the data conductive layer DAT. The insulating layer VIA may include an organic insulating material, such as a generally-used polymer, such as poly(methyl methacrylate) (PMMA) or polystyrene (PS), or a polymer derivative having a phenol-based group, an acryl-based polymer, an imide-based polymer, a polyimide, an acryl-based polymer, and a siloxane-based polymer.

The insulating layer VIA may have a sixth opening OP6 overlapping the storage electrode CE. The storage electrode CE is connected to the driving transistor TR1 on a plane and may receive a driving voltage.

A first electrode 191 may be positioned on the insulating layer VIA. A partition 350 may be positioned on the insulating layer VIA and on (e.g., on a periphery of) the first electrode 191. The partition 350 may have an opening 355 overlapping the first electrode 191. An emission layer 360 may be positioned within the opening 355. A second electrode 270 may be positioned on the partition 350 and the emission layer 360. The first electrode 191, the emission layer 360, and the second electrode 270 may configure the light-emitting element LED.

As described above, in the display device according to embodiments of the present embodiment, the first semiconductor layer ACT1 of the driving transistor TR1, and the second semiconductor layer ACT2 of the switching transistor TR2 include different materials from each other. Through this structure, the reliability of the transistor may be ensured and the driving range thereof in a low gray may be improved. Also, a dummy semiconductor layer ACTD is formed under the second semiconductor layer ACT2 of the switching transistor TR2 and is formed of the same material as the first semiconductor layer ACT1 of the driving transistor TR1. As oxygen is supplied to the second semiconductor layer ACT2 of the switching transistor TR2 through (or from) the dummy semiconductor layer ACTD, the oxygen vacancy is removed (e.g., is filled) inside the second semiconductor layer ACT2, the negative shift of the switching transistor is mitigated or solved, and the problem of the shorting Vth is mitigated or solved.

Now, the manufacturing method of the display device according to an embodiment of the present disclosure will be described, in detail, with reference to accompanying drawings.

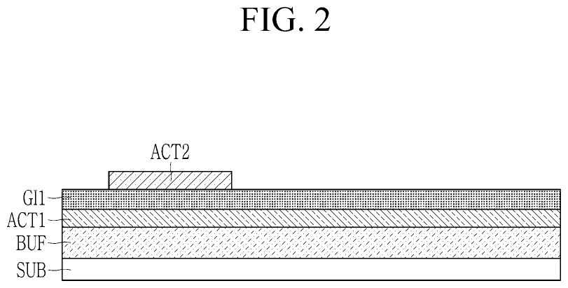

FIG. 2 to FIG. 8 schematic cross-sectional views showing steps of a manufacturing process of the display device described above.

Referring to FIG. 2, a buffer layer BUF, a first semiconductor layer ACT1, a first gate insulating layer GI1, and a second semiconductor layer ACT2 are sequentially formed on a substrate SUB. Referring to FIG. 2, the buffer layer BUF, the first semiconductor layer ACT1, and the first gate insulating layer GI1 may be formed on the entire substrate SUB, and the second semiconductor layer ACT2 may be formed in some regions by using a mask.

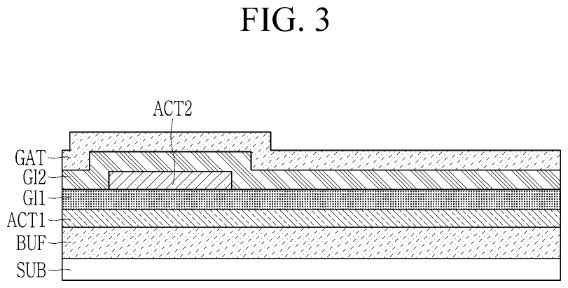

Next, referring to FIG. 3, a second gate insulating layer GI2 and a gate conductive layer GAT are sequentially formed on the second semiconductor layer ACT2 and on the first gate insulating layer GI1.

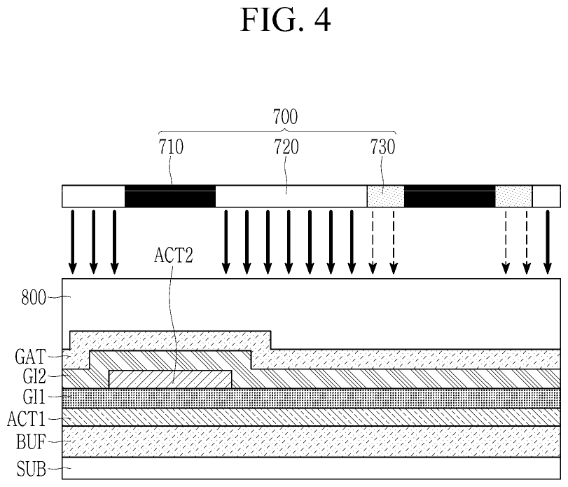

Next, referring to FIG. 4, a photoresist 800 is formed on the gate conductive layer GAT, and a mask 700 is positioned thereover. The mask 700 may have a light blocking region 710, a light transmitting region 720, and a halftone region 730. The light blocking region 710 blocks light, the light transmitting region 720 transmits light, and the halftone region 730 partially transmits light.

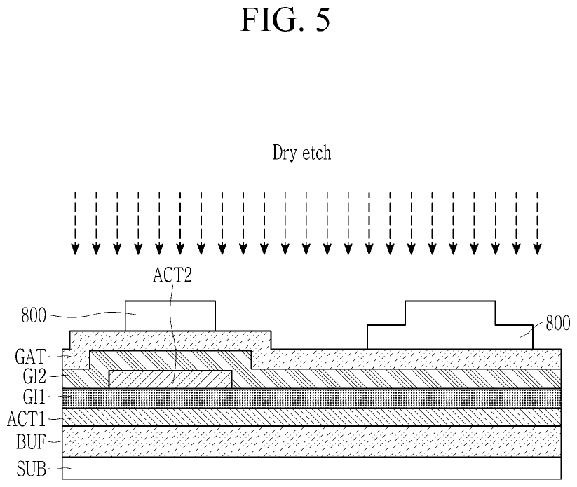

Next, referring to FIG. 5, the photoresist 800 is etched. In some embodiments, this etching may be dry etching. During this etching process, a portion of the photoresist 800 corresponding to (e.g., aligned with or protected by) the light blocking region 710 of the mask 700 from among the photoresist 800 is not etched while a portion of the photoresist 800 corresponding to the light transmitting region 720 of the mask 700 may be completely etched. In addition, a portion of the photoresist 800 corresponding to the halftone region 730 of the mask 700 may be only partially etched.

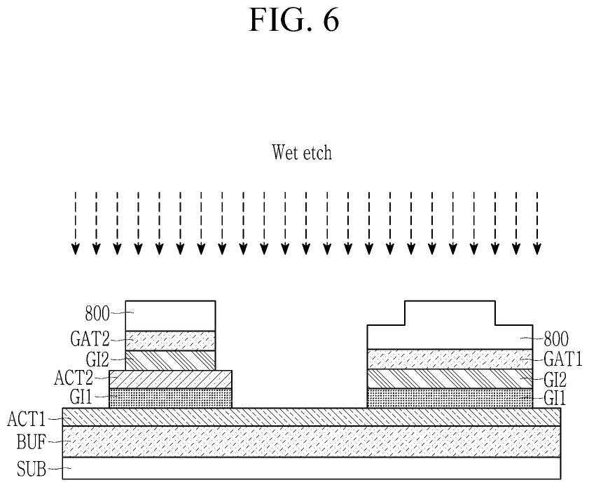

Next, referring to FIG. 6, by using the etched photoresist 800 as a mask, the gate conductive layer GAT, the second gate insulating layer GI2, and the first gate insulating layer GI1 are etched. In some embodiments, this etching may be wet etching. In this process, the first semiconductor layer ACT1 and the second semiconductor layer ACT2 may not be etched due to the etched photoresist 800. Also, the first gate electrode GAT1 and the second gate electrode GAT2 are formed.

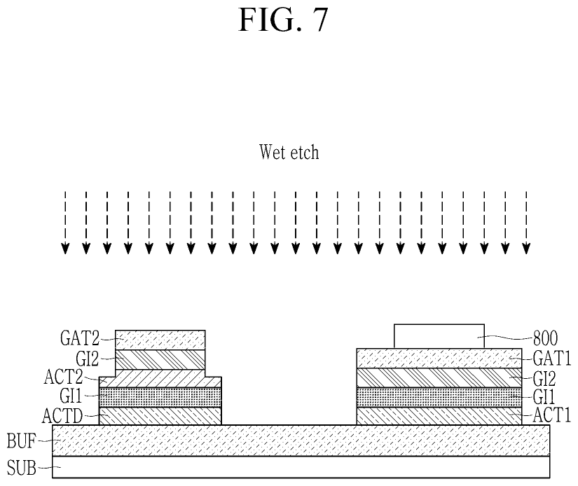

Next, referring to FIG. 7, the first semiconductor layer ACT1 and the second semiconductor layer ACT2 are etched by the wet etching. In this process, the exposed first semiconductor layer ACT1 is etched to form a dummy semiconductor layer ACTD and a first semiconductor layer ACT1. Also, the second semiconductor layer ACT2 may be partially etched so that the thickness thereof may be thinner in some areas. For example, the second semiconductor layer ACT2 not covered by the photoresist 800 may be partially etched. In this process, the photoresist 800 is also etched and the thickness thereof becomes thinner. For example, as shown in FIG. 7, the partially etched photoresist 800 corresponding to the halftone region 730 of the mask 700 may be removed, and in addition, the thickness of the photoresist 800 positioned overlapping with the light blocking region 710 of the mask 700 may be thinned.

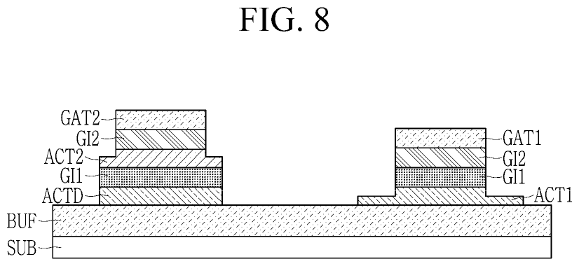

Next, referring to FIG. 8, the gate conductive layer GAT, the second gate insulating layer GI2, and the first gate insulating layer GI1 are etched using the etched photoresist 800 as a mask. In this process, the first semiconductor layer ACT1 may be partially etched so that the thickness thereof may be thinner at some areas. For example, the second semiconductor layer ACT2 not covered by the first gate electrode GAT1, the second gate insulating layer GI2, and the first gate insulating layer GI1 may be partially etched.

In this process, the photoresist 800 may be removed. Next, the display device shown in FIG. 1 may be manufactured through the formation process of the interlayer insulating layer, the data conductive layer, the first electrode, and the like. That is, through the manufacturing process steps shown in FIG. 2 to FIG. 8, the driving transistor including the first semiconductor layer ACT1 and the switching transistor including the second semiconductor layer ACT2 including a different material from the first semiconductor layer ACT1 may be formed. In such an embodiment, the dummy semiconductor layer ACTD is positioned under the second semiconductor layer ACT2, and the dummy semiconductor layer ACTD, which includes the same material as the first semiconductor layer ACT1, supplies oxygen to the second semiconductor layer ACT2 so that the oxygen vacancy of the second semiconductor layer ACT2 may be removed.

While the present disclosure has been described in connection with what is presently considered to be practical embodiments, it is to be understood that the present disclosure is not limited to the disclosed embodiments. On the contrary, the present disclosure covers various modifications and equivalent arrangements included within the spirit and scope of the appended claims and their equivalents.

What is claimed is:

1. A display device comprising:
a substrate;
a first semiconductor layer and a dummy semiconductor layer on the same layer on a surface of the substrate and comprising the same material as each other;
a second semiconductor layer overlapping the dummy semiconductor layer in a direction perpendicular to the surface of the substrate, the first semiconductor layer and the second semiconductor layer comprising different materials from each other;
a first transistor comprising the first semiconductor layer, a first source electrode, and a first drain electrode, the first source electrode and the first drain electrode being connected to the first semiconductor layer;
a second transistor comprising the second semiconductor layer, a second source electrode, and a second drain electrode, the second source electrode and the second drain electrode being connected to the second semiconductor layer; and
a light-emitting element connected to the first transistor.

2. The display device of claim 1, wherein the first semiconductor layer and the dummy semiconductor layer comprise IGZO (indium gallium zinc oxide).

3. The display device of claim 2, wherein the second semiconductor layer comprises indium tin gallium zinc oxide (ITGZO).

4. The display device of claim 3, further comprising a first gate insulating layer between the dummy semiconductor layer and the second semiconductor layer,
wherein the dummy semiconductor layer, the first gate insulating layer, and the second semiconductor layer have the same planar shape.

5. The display device of claim 4, further comprising a second gate insulating layer and a second gate electrode on the second semiconductor layer,
wherein the second gate insulating layer and the second gate electrode have the same planar shape.

6. The display device of claim 5, wherein a thickness of a portion of the second semiconductor layer overlapping the second gate insulating layer is thicker than a thickness of a portion of the second semiconductor layer that does not overlap the second gate insulating layer.

7. The display device of claim 4, further comprising a first gate insulating layer, a second gate insulating layer, and a first gate electrode on the first semiconductor layer,
wherein the first gate insulating layer, the second gate insulating layer, and the first gate electrode have the same planar shape.

8. The display device of claim 7, wherein a portion of the first semiconductor layer overlapping the first gate insulating layer is thicker than a portion of the first semiconductor layer that does not overlap the first gate insulating layer.

9. The display device of claim 8, wherein a thickness of the dummy semiconductor layer and a thickness of the portion of the first semiconductor layer overlapping the first gate insulating layer are the same.

10. The display device of claim 1, further comprising a light blocking layer between the substrate and the first semiconductor layer,
wherein the first source electrode directly contacts the light blocking layer.

11. The display device of claim 1, wherein the first source electrode, the first drain electrode, the second source electrode, and the second drain electrode are on the same layer.

12. A manufacturing method of a display device, the method comprising:
forming a first semiconductor material on a substrate;
forming a first gate insulating layer on the first semiconductor material;
forming a second semiconductor material on the first gate insulating layer, the second semiconductor material comprises at least the same material as the first semiconductor material;
patterning the second semiconductor material to form a second semiconductor layer; and
etching the first semiconductor material to form a dummy semiconductor layer overlapping the second semiconductor layer and a first semiconductor layer that does not overlap the second semiconductor layer.

13. The manufacturing method of the display device of claim 12, wherein the first semiconductor material is indium gallium zinc oxide (IGZO).

14. The manufacturing method of the display device of claim 13, wherein the second semiconductor material is indium tin gallium zinc oxide (ITGZO).

15. The manufacturing method of the display device of claim 14, further comprising:
forming a second gate insulating layer on the second semiconductor material; and
forming a gate conductive layer on the second gate insulating layer.

16. The manufacturing method of the display device of claim 15, further comprising etching the gate conductive layer, the second gate insulating layer, and the first gate insulating layer.

17. The manufacturing method of the display device of claim 16, wherein the gate conductive layer, the second gate insulating layer, and the first gate insulating layer are etched by using a halftone mask.

18. The manufacturing method of the display device of claim 17, wherein after the etching of the gate conductive layer, the second gate insulating layer, and the first gate insulating layer, a portion of the second semiconductor layer does not overlap the second gate insulating layer.

19. The manufacturing method of the display device of claim 18, wherein a portion of the second semiconductor layer overlapping the second gate insulating layer is thicker than the portion of the second semiconductor layer that does not overlap the second gate insulating layer.

20. The manufacturing method of the display device of claim 17, wherein after the etching of the gate conductive layer, the second gate insulating layer, and the first gate insulating layer, a portion of the first semiconductor layer does not overlap the first gate insulating layer.
